(19) United States
(12) Patent Application Publication
(10) Pub. No.: US 2015/0309239 A1
(43) Pub. Date: Oct. 29, 2015

(54) LCD MODULE AND ELECTRONIC DEVICE INCLUDING THE SAME

(71) Applicant: Samsung Electronics Co., Ltd., Gyeonggi-do (KR)

(72) Inventors: Heeryoul Choi, Seoul (KR); Dongseop Lee, Seoul (KR)

(21) Appl. No.: 14/700,014

(22) Filed: Apr. 29, 2015

(30) Foreign Application Priority Data
Apr. 29, 2014 (KR) 10-2014-0051948

(51) Int. Cl. F21V 8/00; H05K 1/02

(52) U.S. Cl. CPC G02B 6/0031; H05K 1/028; G02B 6/0083; H05K 2201/10136

(57) ABSTRACT

An LCD module according to various embodiments of the present disclosure includes a reflective sheet for reflecting light exiting from a light guide plate to input the light toward the light guide plate again, and a metal sheet bonded to a rear surface of the reflective sheet that is opposite to a light incident surface thereof.

### CROSS-REFERENCE TO RELATED APPLICATION(S) AND CLAIM OF PRIORITY

The present application is related to and claims priority from and the benefit under 35 U.S.C. §119(a) of Korean Patent Application No. 10-2014-0051948, filed on Apr. 29, 2014, which is hereby incorporated by reference for all purposes as if fully set forth herein.

### TECHNICAL FIELD

Various embodiments of the present disclosure relate to an LCD module and an electronic device including the same.

### BACKGROUND

In recent years, display device fields have been rapidly developed to keep pace with the information age and accordingly, Flat Panel Display (FPD) devices having the advantages of slimness, weight reduction, and low power consumption, such as Liquid Crystal Display (LCD) devices, Organic Light Emitting Diodes (OLEDs), Plasma Display Panel (PDP) devices, Electroluminescence Display (ELD) devices, and Field Emission Display (FED) devices, have been being spotlighted as display devices to replace Cathode Ray Tubes (CRTs). Among the FPDs, the LCD devices have been employed for a variety of electronic devices due to their excellence in displaying videos and high contrast ratio.

Such LCD devices may include a liquid crystal substrate, a backlight unit for emitting light toward the liquid crystal substrate, a Flexible Printed Circuit (FPC), and a mold frame for supporting them.

### SUMMARY

Backlight units of LCD devices according to the related art include a reflective sheet (or reflector) for reflecting light emitted from a light source (or LED) to input it toward a light guide plate again. The reflective sheet according to the related art can be directly brought into contact with or attached to an FPC. Alternatively, a cushion sheet can be interposed between the reflective sheet and the FPC.

However, in cases where the reflective sheet according to the related art is directly brought into contact with or attached to the FPC, the reflective sheet may fail to perform its function due to deformation (for example, sheet wrinkles). Alternatively, in cases where the thick cushion sheet is interposed between the reflective sheet and the FPC, the thicknesses of the LCD devices as well as those of the backlight units may be increased.

To address the above-discussed deficiencies, it is a primary object to provide an LCD module that can protect a reflective sheet and achieve slimness (or thinness) thereof, and an electronic device including the same.

In accordance with one aspect of the present disclosure, an LCD module includes a reflective sheet for reflecting light exiting from a light guide plate to input the light toward the light guide plate again, and a metal sheet bonded to a rear surface of the reflective sheet that is opposite to a light incident surface thereof.

In accordance with another aspect of the present disclosure, an electronic device includes a reflective sheet for reflecting light exiting from a light guide plate to input the light toward the light guide plate again, and a metal sheet bonded to a rear surface of the reflective sheet that is opposite to a light incident surface thereof.

Various embodiments of the present disclosure provide an LCD module that can protect a reflective sheet, achieve slimness (or thinness) thereof, and dissipate heat generated from the interior thereof, and an electronic device including the same.

Before undertaking the DETAILED DESCRIPTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates a block diagram of an electronic device according to various embodiments of the present disclosure;

FIG. 2 illustrates a side view of an LCD module according to an embodiment of the present disclosure;

FIG. 3 illustrates a side view of an LCD module according to another embodiment of the present disclosure; and

FIG. 4 illustrates a block diagram of hardware according to various embodiments of the present disclosure.

### DETAILED DESCRIPTION

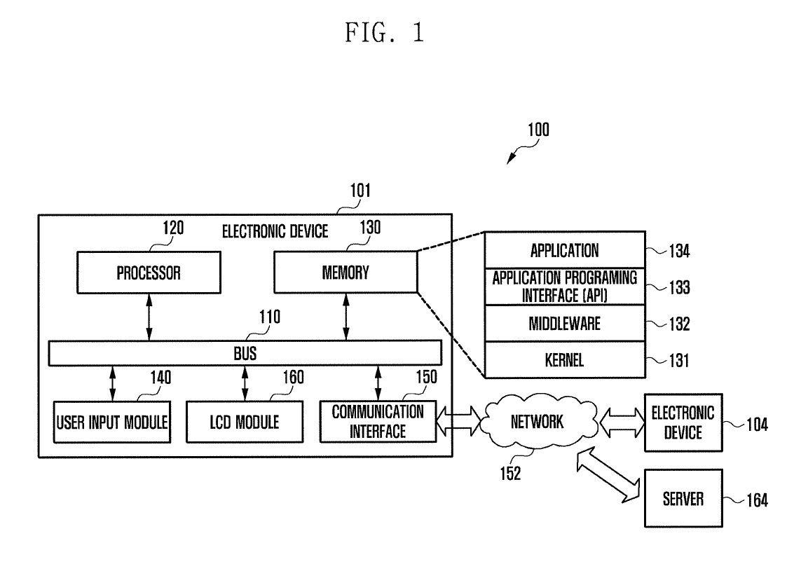

FIGS. 1 through 4, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged electronic device or system. Hereinafter, the present disclosure will be described with reference to the accompanying drawings. The present disclosure may have various embodiments, and modifications and changes may be made therein. Therefore, the present disclosure will be described in detail with reference to particular embodiments shown in the accompanying drawings. However, it should be understood that there is no intent to limit the present disclosure to the particular forms, and the present disclosure should be construed to cover all modifications, equivalents, and/or alternatives falling within the spirit and scope of the present disclosure. In describing the drawings, similar elements are designated by similar reference numerals.

As used in the present disclosure, the expression “include” or “may include” or “can include” refers to the existence of a corresponding function, operation, or constituent element, and does not limit one or more additional functions, operations, or constituent elements. Further, as used in the present disclosure, the term such as “include” or “have” may be construed to denote a certain characteristic, number, step, operation, constituent element, component or a combination thereof, but may not be construed to exclude the existence of or a possibility of addition of one or more other characteristics, numbers, steps, operations, constituent elements, components or combinations thereof.

As used in the present disclosure, the expression “and/or” includes any or all combinations of words enumerated together. For example, the expression “A or B” or “at least one of A and B” may include A, may include B, or may include both A and B.

While expressions including ordinal numbers, such as “first” and “second”, as used in the present disclosure may modify various constituent elements, such constituent elements are not limited by the above expressions. For example, the above expressions do not limit the sequence and/or importance of the corresponding constituent elements. The above expressions may be used merely for the purpose of distinguishing a constituent element from other constituent elements. For example, a first user device and a second user device indicate different user devices although both are user devices. For example, a first constituent element may be termed a second constituent element, and likewise a second constituent element may also be termed a first constituent element without departing from the scope of the present disclosure.

When a component is referred to as being “connected” or “accessed” to any other component, it should be understood that the component may be directly connected or accessed to the other component, but another new component may also be interposed between them. Contrarily, when a component is referred to as being “directly connected” or “directly accessed” to any other component, it should be understood that there is no new component between the component and the other component.

The teens as used in various embodiments of the present disclosure are merely for the purpose of describing particular embodiments and are not intended to limit the present disclosure. Singular forms are intended to include plural forms unless the context clearly indicates otherwise.

Unless defined otherwise, all terms used herein, including technical terms and scientific terms, have the same meaning as commonly understood by a person of ordinary skill in the art to which the present disclosure pertains. Such terms as those defined in a generally used dictionary are to be interpreted to have the meanings equal to the contextual meanings in the relevant field of art, and are not to be interpreted to have ideal or excessively formal meanings unless clearly defined in the present disclosure.

In this disclosure, an electronic device is a device that involves a communication function. For example, an electronic device is a smart phone, a tablet PC (Personal Computer), a mobile phone, a video phone, an e-book reader, a desktop PC, a laptop PC, a netbook computer, a PDA (Personal Digital Assistant), a PMP (Portable Multimedia Player), an MP3 player, a portable medical device, a digital camera, or a wearable device (for example, an HMD (Head-Mounted Device) such as electronic glasses, electronic clothes, an electronic bracelet, an electronic necklace, electronic tattoos, an electronic appcessory, or a smart watch).

According to some embodiments, an electronic device is a smart home appliance that involves a communication function. For example, an electronic device can be a TV, a DVD (Digital Video Disk) player, audio equipment, a refrigerator, an air conditioner, a vacuum cleaner, an oven, a microwave, a washing machine, an air cleaner, a set-top box, a TV box (e.g., SAMSUNG HOMESYNC™, APPLE TV®, GOOGLE TV®, and the like), a game console, an electronic dictionary, an electronic key, a camcorder, or an electronic picture frame.

According to some embodiments, an electronic device is a medical device (such as, MRA (Magnetic Resonance Angiography), MRI (Magnetic Resonance Imaging), CT (Computed Tomography), ultrasonography, and the like), a navigation device, a GPS (Global Positioning System) receiver, an EDR (Event Data Recorder), an FDR (Flight Data Recorder), a car infotainment device, electronic equipment for ship (such as, a marine navigation system, a gyrocompass, and so forth), avionics, security equipment, an industrial or home robot, an automatic teller machine of financial institutions, or point of sales of stores.

According to some embodiments, an electronic device is furniture or part of a building or construction having a communication function, an electronic board, an electronic signature receiving device, a projector, or various measuring instruments (such as, a water meter, an electric meter, a gas meter, a wave meter, and so forth). An electronic device disclosed herein can be one of the above-mentioned devices or any combination thereof. Further, the electronic device according to the present disclosure can be a flexible device. It is noted that the above-mentioned electronic devices are exemplary only and not to be considered as a limitation of this disclosure.

Hereinafter, an electronic device according to various embodiments of the present disclosure will be discussed with reference to the accompanying drawings. The term “a user” as used in various embodiments may refer to any person who uses an electronic device or any other device (such as, an artificial intelligence electronic device) using an electronic device.

FIG. 1 is a block diagram illustrating a network environment 100 including therein an electronic device 101 in accordance with an embodiment of the present disclosure. Electronic device 101 includes, but not limited to, a bus 110, a processor 120, a memory 130, an input/output interface 140, a LCD module 160, and a communication interface 150.

The bus 110 is a circuit designed for connecting the above-discussed elements and communicating data (such as, a control message) between such elements.

The processor 120 receives commands from the other elements (for example, the memory 130, the input/output interface 140, the LCD module 160, or the communication interface 150, and so forth.) through the bus 110, interpret the received commands, and perform the arithmetic or data processing based on the interpreted commands.

The memory 130 stores therein commands or data received from or created at the processor 120 or other elements (for example, the input/output interface 140, the LCD module 160, the communication interface 150, and so forth). The memory 130 includes programming modules such as a kernel 131, a middleware 132, an application programming interface (API) 133, and an application 134. Each of the programming modules can be composed of software, firmware, hardware, and any combination thereof.

The kernel 131 controls or manages system resources (for example, the bus 110, the processor 120, or the memory 130, and so forth) used for performing operations or functions of the other programming modules, for example, the middleware 132, the API 133, or the application 134. Additionally, the kernel 131 offers an interface that allows the middleware 132, the API 133 or the application 134 to access, control or manage individual elements of the electronic device 101.

The middleware 132 performs intermediation by which the API 133 or the application 134 communicates with the kernel 131 to transmit or receive data. Additionally, in connection with task requests received from the applications 134, the middleware 132 performs a control (for example, scheduling or load balancing) for the task request by using technique such as assigning the priority for using a system resource of the electronic device 101 (for example, the bus 110, the processor 120, or the memory 130, and so forth) to at least one of the applications 134.

The API 133, which is an interface for allowing the application 134 to control a function provided by the kernel 131 or the middleware 132, includes, for example, at least one interface or function (for example, a command) for a file control, a window control, an image processing, a text control, and the like.

According to embodiments, the application 134 includes an SMS/MMS application, an email application, a calendar application, an alarm application, a health care application (for example, an application for measuring quantity of motion or blood sugar), an environment information application (for example, an application for offering information about atmospheric pressure, humidity, or temperature, and so forth), and the like. Additionally or alternatively, the application 134 can be an application associated with an exchange of information between the electronic device 101 and any external electronic device (for example, an external electronic device 104). This type application includes a notification relay application for delivering specific information to an external electronic device, or a device management application for managing an external electronic device.

For example, the notification relay application includes a function to deliver notification information created at any other application of the electronic device 101 (for example, the SMS/MMS application, the email application, the health care application, or the environment information application, and so forth) to an external electronic device (for example, the electronic device 104). Additionally or alternatively, the notification relay application receives notification information from an external electronic device and offer it to a user. The device management application manages (for example, install, remove or update) a certain function (a turn-on/turn-off of an external electronic device (or some components thereof), or an adjustment of brightness (or resolution) of a display) of any external electronic device communicating with the electronic device 101, a certain application operating at such an external electronic device, or a certain service (for example, a call service or a message service) offered by such an external electronic device.

According to embodiments, the application 134 includes a specific application specified depending on attributes (for example, a type) of an external electronic device (for example, the electronic device 104). For example, in case an external electronic device is an MP3 player, the application 134 includes a specific application associated with a play of music. Similarly, in case an external electronic device is a portable medical device, the application 134 includes a specific application associated with a health care. In an embodiment, the application 134 includes at least one of an application assigned to the electronic device 101 or an application received from an external electronic device (for example, the server 106 or the electronic device 104).

The input/output interface 140 delivers commands or data, entered by a user through an input/output unit (for example, a sensor, a keyboard, or a touch screen), to the processor 120, the memory 130, the communication interface 160, or the application control module 170 via the bus 110. For example, the input/output interface 140 offers data about a user's touch, entered through the touch screen, to the processor 120. Also, through the input/output unit (for example, a speaker or a LCD module), the input/output interface 140 outputs commands or data, received from the processor 120, the memory 130, or the communication interface 150 via the bus 110. For example, the input/output interface 140 outputs voice data, processed through the processor 120, to a user through the speaker.

The communication interface 150 performs a communication between the electronic device 101 and any external electronic device (for example, the electronic device 104 of the server 106). For example, the communication interface 150 communicates with any external device by being connected with a network 152 through a wired or wireless communication. A wireless communication includes, but not limited to, at least one of WiFi (Wireless Fidelity), BT (BLUETOOTH®), NFC (Near Field Communication), GPS (Global Positioning System), or a cellular communication (e.g., LTE, LTE-A, CDMA, WCDMA, UMTS, WiBro, or GSM, and so forth). A wired communication includes, but not limited to, at least one of USB (Universal Serial Bus), HDMI (High Definition Multimedia Interface), RS-232 (Recommended Standard 232), or POTS (Plain Old Telephone Service).

According to an embodiment, the network 152 is a communication network, which includes at least one of a computer network, an internet, an internet of things, or a telephone network. According to an embodiment, a protocol (for example, transport layer protocol, data link layer protocol, or physical layer protocol) for a communication between the electronic device 101 and any external device is supported by at least one of the application 134, the API 133, the middleware 132, the kernel 131, or the communication interface 150.

According to an embodiment, the server 106 is supported by performing at least one operation among the operations (or functions) obtained from the electronic device 101.

The LCD module 160 displays various information (such as, multimedia data, text data, and the like) to a user. A further description about the LCD module 160 according to the various embodiments of the present disclosure will be given hereinafter.

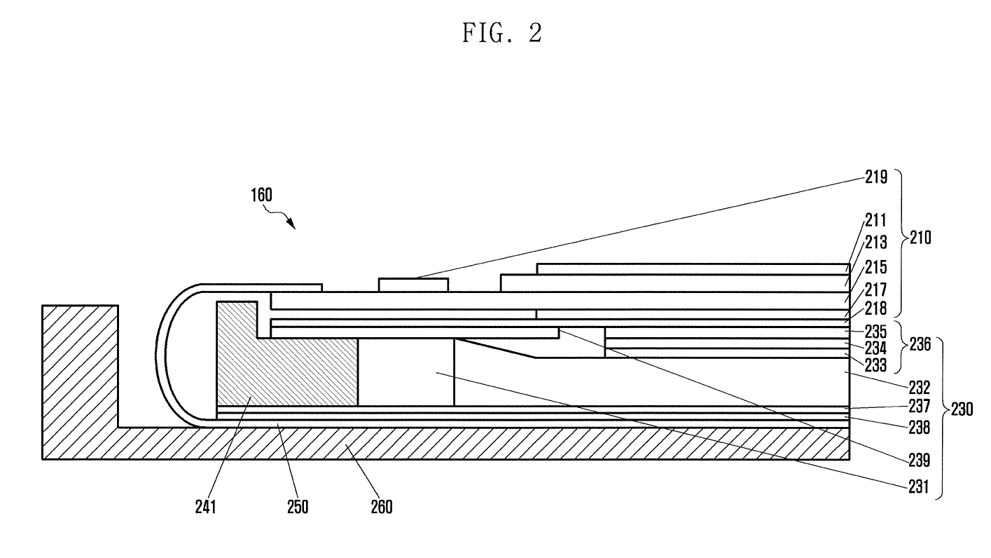

FIG. 2 is a side view of an LCD module 160 of an electronic device (for example, the electronic device 101) according to an embodiment of the present disclosure.

Referring to FIG. 2, the LCD module 160 includes, for example, a liquid crystal substrate 210, a backlight unit 230, a mold frame 241, a Flexible Printed Circuit (FPC) 250, and a bracket 260.

The liquid crystal substrate 210 displays desired images, for example, by changing the transmittance of light incident (or emitted) from the backlight unit 230 depending upon electrical stimuli applied by liquid crystal. The liquid crystal substrate 210 includes, for example, an upper polarizing plate 211, a color filter substrate 213, a Thin Film Transistor (TFT) substrate 215, a lower polarizing plate 217, a bonding layer 218, and a Liquid crystal display Driver Integrated circuit (LDI) 219.

The TFT substrate 215 includes, for example, a plurality of gate lines and data lines that are formed in the shape of a matrix. A pixel electrode and a Thin Film Transistor (TFT) can be formed at each of the intersections of the plurality of gate lines and data lines. A signal voltage applied through the thin film transistor can be applied to liquid crystal (not illustrated) by the pixel electrode, and the liquid crystal can be aligned depending upon the signal voltage to determine light transmittance.

The color filter substrate 213 is disposed, for example, to face the TFT substrate 215, and includes a color filter constituted by RGB pixels that transmit light to express colors and a transparent common electrode (for example, Indium Tin Oxide (ITO)). According to an embodiment, the color filter substrate 213 has a smaller area than the TFT substrate 215. An overlapping region where the color filter substrate 213 and the TFT substrate 215 overlap each other can be a screen display region (or an active region) where images are displayed, and a non-overlapping region (or a peripheral region around the screen display region) where the color filter substrate 213 and the TFT substrate 215 do not overlap each other can be a non-screen display region (or referred to as a black matrix) where images are not displayed.

The upper and lower polarizing plates 211 and 217 can be placed on, for example, the color filter substrate 213 and the TFT substrate 215, respectively, and transmits light in a particular direction. According to an embodiment, the upper and lower polarizing plates 211 and 217 is arranged to polarize incident light in a crossed state.

The bonding layer 218 is attached to, for example, the rear surface of the lower polarizing plate 217 and supports the liquid crystal substrate 210. According to an embodiment, the bonding layer 218 shields light to prevent leakage of the light to the non-screen display region.

The LCD driver IC 219 is placed, for example, at the lower portion of the color filter substrate 213 in which the non-screen display region is formed. According to an embodiment, the LCD driver IC 219 includes a terminal for supplying electric power to the liquid crystal substrate 210. One side of the terminal is connected to the FPC 250, and the other side of the terminal is connected to the gate lines and the data lines of the TFT substrate 215.

The backlight unit 230 is placed, for example, below the liquid crystal substrate 210 and includes a light source 231 (or a Light Emitting Diode (LED)), a light guide plate 232, an optical sheet 236, a reflective sheet 237 (or a reflector), a thin film sheet 238, and an LED FPC 239.

The light source (or LED) 231 is a light source of, for example, the backlight unit 230 and is placed on a side of the light guide plate 232. In an embodiment, the backlight unit 230 is an edge type backlight unit in which the light source is placed around the edge of the light guide plate 232. According to another embodiment, the backlight unit 230 also can be a direct backlight unit in which the light source 231 is placed below the light guide plate 232.

For example, the light guide plate 232 can uniformly provide light, which is input from the light source 231, to the rear surface of the liquid crystal substrate 210. To this end, the light guide plate 232 allows the light incident from the light source 231 to uniformly spread into the wide region of the light guide plate 232 while travelling within the light guide plate 232 through a lot of total reflection. According to an embodiment, the light guide plate 232 includes a pattern of a particular shape on the rear surface thereof to provide uniform light. For example, the pattern includes an elliptical pattern, a polygonal pattern, or a hologram pattern to guide light incident to the interior of the light guide plate 232.

The optical sheet 236 is placed, for example, on the light guide plate 232 and spreads and condenses light incident through the light guide plate 232 to adjust a progress direction of the light. According to an embodiment, the optical sheet 236 includes a diffusion sheet 233 and first and second prism sheets 234 and 235 functioning as a light-condensing sheet. The diffusion sheet 233, for example, diffuses light incident from the light guide plate 232 to prevent the light from being partially condensed. The first and second prism sheets 234 and 235, for example, condense the light incident from the diffusion sheet 233 in a first direction and a second direction perpendicular thereto. Accordingly, the light having passed through the light-condensing sheet is orthogonally input to the rear surface of the liquid crystal substrate 210.

The reflective sheet 237, for example, reflects light travelling toward the rear surface of the light guide plate 232 to input the light toward the light guide plate 232 again, thereby reducing light loss and enhancing the luminance of the LCD module 160.

The thin film sheet 238 is placed, for example, on the rear surface of the reflective sheet 237. According to an embodiment, the thin film sheet 238 protects the reflective sheet 237. According to an embodiment, the thin film sheet 238 prevents the reflective sheet 237 implemented in a thin film shape from being deformed by contact with the FPC 250 or the bracket 260.

According to an embodiment, the thin film sheet 238 is formed of metal (for example, Cu or Al). In cases where the thin film sheet 238 is formed of metal, the thin film sheet 238, for example, dissipates heat released from the LCD driver IC 219 or the light source 231 to the outside. In an embodiment, the thin film sheet 238 has a thickness of 100 μm or less. In an embodiment, the thin film sheet 238 is bonded (stacked, attached, or laminated) on the reflective sheet 237. In another embodiment, the thin film sheet 238 is attached to the reflective sheet 237 through an adhesive member (for example, a double-sided adhesive tape). The rear surface of the thin film sheet 238 is attached to or be brought into contact with the FPC 250 as illustrated in FIG. 2 or is placed above the FPC 250 by a predetermined gap. For example, the thin film sheet 238 can be attached to the upper portion of the FPC 250 through an adhesive member (for example, a double-sided adhesive tape).

The LED FPC 239 is placed, for example, on the upper surfaces of the light source 231 and the mold frame 241 and supplies electric power to the light source 231. Although not illustrated in FIG. 2, the LED FPC 239 can be attached to the mold frame 241 through an adhesive member (for example, a double-sided adhesive tape).

The mold frame 241, for example, fixes and supports the backlight unit 230 and the liquid crystal substrate 210. For example, as illustrated in FIG. 2, the mold frame 241 has a side wall that is formed on a side thereof to be higher than the backlight unit 230 to support the backlight unit 230.

The FPC 250, for example, supplies signals and electric power to the LCD driver IC 219. For example, a part of the FPC 250 can be brought into contact with (or attached to) a part of the TFT substrate 215, and the FPC 250 supplies signals and electric power to the LCD driver IC 219 through a connecting part (not illustrated) that connects the FPC 250 and the LCD driver IC 219. Another part of the FPC 250 can be placed between the upper surface of the bracket 260 and the rear surface of the thin film sheet 238.

According to an embodiment, the bracket 260 includes an FPC and function to protect and support the liquid crystal substrate 210 and the backlight unit 230.

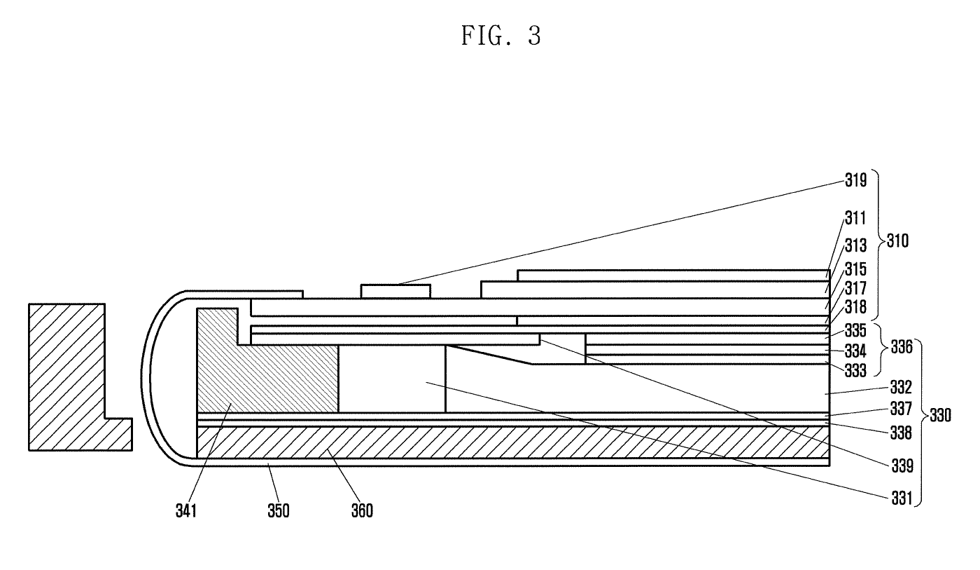

FIG. 3 is a side view of an LCD module according to another embodiment of the present disclosure.

Comparing FIGS. 2 and 3, the LCD module 160 illustrated in FIG. 2 can be implemented in such a form that the FPC 250 surrounds the liquid crystal substrate 210 and the backlight unit 230 and is stacked on the upper surface of the bracket 260, with one surface thereof brought into contact with one surface of the bracket 260. An LCD module 160 illustrated in FIG. 3 can be implemented in such a form that an FPC 350 passes through a hole formed at an edge of a bracket 360 and surrounds the rear surface of the bracket 360. Hereinafter, repetitive descriptions of elements that are the same as those described with reference to FIG. 2 will be omitted. According to an embodiment, a thin film sheet 338 is placed on the rear surface of a reflective sheet 337. The thin film sheet 338 protects the reflective sheet 337. For example, the thin film sheet 338 prevents the reflective sheet 337 implemented in a thin film shape from being deformed by contact with the FPC 350 or the bracket 360. According to an embodiment, the thin film sheet 338 is formed of metal (for example, Cu or Al). In cases where the thin film sheet 338 is formed of metal, the thin film sheet 338, for example, dissipates heat released from an LCD driver IC 319 or a light source 331 to the outside. In an embodiment, the thin film sheet 338 has a thickness of 100 μm or less. In an embodiment, the thin film sheet 338 is bonded (stacked, attached, or laminated) on the reflective sheet 337. In another embodiment, the thin film sheet 338 is attached to the reflective sheet 337 through an adhesive member (for example, a double-sided adhesive tape). The rear surface of the thin film sheet 338 is attached to or be brought into contact with the bracket 360 as illustrated in FIG. 3 or is placed above the FPC 350 by a predetermined gap. For example, the thin film sheet 338 can be attached to the upper portion of the bracket 360 through an adhesive member (for example, a double-sided adhesive tape).

According to an embodiment, an LCD module includes a reflective sheet for reflecting light exiting from a light guide plate to input the light toward the light guide plate again, and a thin film sheet having a surface bonded to a rear surface of the reflective sheet that is opposite to a light incident surface thereof.

According to an embodiment, the thin film sheet is formed of metal.

According to an embodiment, the metal is copper (Cu) or aluminum (Al).

According to an embodiment, the thin film sheet has a thickness of 100 μm or less.

According to an embodiment, the LCD module further includes a Flexible Printed Circuit (FPC) and the thin film sheet is attached to, or brought into contact with, an upper portion of the FPC.

According to an embodiment, the thin film sheet is attached to the FPC through an adhesive member.

According to an embodiment, the LCD module further includes a bracket, and the FPC is stacked on the bracket.

According to an embodiment, the LCD module further includes a bracket, and the thin film sheet is stacked on and attached to the bracket.

According to an embodiment, the LCD module further includes an FPC, and a portion of the FPC is placed on a rear surface of the bracket, which is opposite to the surface of the bracket on which the thin film sheet is stacked, through a hole formed in the bracket.

According to an embodiment, the LCD module further includes a bracket, and the thin film sheet is stacked on the bracket and is brought into contact with or spaced a predetermined gap apart from the bracket.

According to an embodiment, an electronic device involving an LCD module includes a reflective sheet for reflecting light exiting from a light guide plate to input the light toward the light guide plate again, and a thin film sheet having a surface bonded to a rear surface of the reflective sheet that is opposite to a light incident surface thereof.

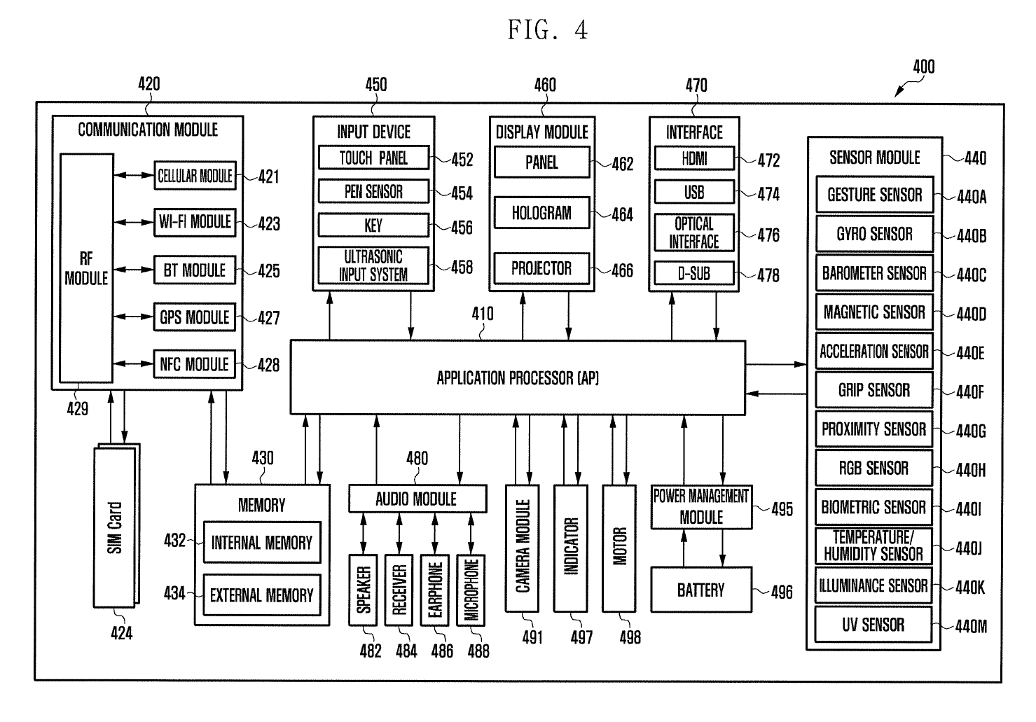

FIG. 4 is a block diagram illustrating an electronic device 400 in accordance with an embodiment of the present disclosure. The electronic device 400 forms, for example, the whole or part of the electronic device 101 shown in FIG. 1. Electronic device 400 includes at least one application processor (AP) 410, a communication module 420, a subscriber identification module (SIM) card 424, a memory 430, a sensor module 440, an input unit 450, a display module 460, an interface 470, an audio module 480, a camera module 491, a power management module 495, a battery 496, an indicator 497, and a motor 498.

The AP 410 drives an operating system or applications, control a plurality of hardware or software components connected thereto, and also perfoinis processing and operation for various data including multimedia data. The AP 410 is formed of system-on-chip (SoC), for example. According to an embodiment, the AP 410 further includes a graphic processing unit (GPU) (not shown).

The communication module 420 (for example, the communication interface 150) performs data communication with any other electronic device (for example, the electronic device 104 or the server 106) connected to the electronic device 400 (for example, the electronic device 101) through the network. According to an embodiment, the communication module 420 includes therein a cellular module 421, a WiFi module 423, a BT module 425, a GPS module 427, and an NFC module 428.

The cellular module 421 supports a voice call, a video call, a message service, an internet service, or the like through a communication network (for example, LTE, LTE-A, CDMA, WCDMA, UMTS, WiBro, or GSM, etc.). Additionally, the cellular module 221 performs identification and authentication of the electronic device in the communication network, using the SIM card 424. According to an embodiment, the cellular module 421 performs at least part of functions the AP 410 can provide. For example, the cellular module 421 performs at least part of a multimedia control function.

According to an embodiment, the cellular module 421 includes a communication processor (CP). Additionally, the cellular module 421 is formed of SoC, for example. Although some elements such as the cellular module 421 (for example, the CP), the memory 430, or the power management module 495 are shown as separate elements being different from the AP 410 in FIG. 4, the AP 410 is formed to have at least part (for example, the cellular module 421) of the above elements in an embodiment.

According to an embodiment, the AP 410 or the cellular module 421 (for example, the CP) loads commands or data, received from a nonvolatile memory connected thereto or from at least one of the other elements, into a volatile memory to process them. Additionally, the AP 410 or the cellular module 421 stores data, received from or created at one or more of the other elements, in the nonvolatile memory.

Each of the WiFi module 423, the BT module 425, the GPS module 427 and the NFC module 428 includes a processor for processing data transmitted or received there through. Although FIG. 4 shows the cellular module 421, the WiFi module 423, the BT module 425, the GPS module 427 and the NFC module 428 as different blocks, at least part of them is contained in a single IC (Integrated Circuit) chip or a single IC package in an embodiment. For example, at least part (for example, the CP corresponding to the cellular module 421 and a WiFi processor corresponding to the WiFi module 423) of respective processors corresponding to the cellular module 421, the WiFi module 423, the BT module 425, the GPS module 427 and the NFC module 428 is formed as a single SoC.

The communication module 420 further includes a RF module. The RF module transmits and receives data, such as, RF signals or any other electric signals. Although not shown, the RF module includes a transceiver, a PAM (Power Amp Module), a frequency filter, an LNA (Low Noise Amplifier), or the like. Also, the RF module includes any component, for example, a wire or a conductor, for transmission of electromagnetic waves in a free air space. Although FIG. 4 shows that the cellular module 421, the WiFi module 423, the BT module 425, the GPS module 427 and the NFC module 428 share the RF module, at least one of them performs transmission and reception of RF signals through a separate RF module in an embodiment.

The SIM card 424 is a specific card formed of SIM and is inserted into a slot (not shown) formed at a certain place of the electronic device. The SIM card 424 contains therein an ICCID (Integrated Circuit Card IDentifier) or an IMSI (International Mobile Subscriber Identity).

The memory 430 (for example, the memory 130) includes an internal memory 432 and an external memory 434. The internal memory 432 includes, for example, at least one of a volatile memory (for example, DRAM (Dynamic RAM), SRAM (Static RAM), SDRAM (Synchronous DRAM), and so forth) or a nonvolatile memory (for example, OTPROM (One Time Programmable ROM), PROM (Programmable ROM), EPROM (Erasable and Programmable ROM), EEPROM (Electrically Erasable and Programmable ROM), mask ROM, flash ROM, NAND flash memory, NOR flash memory, and so forth).

According to an embodiment, the internal memory 432 has the form of an SSD (Solid State Drive). The external memory 434 includes a flash drive, for example, CF (Compact Flash), SD (Secure Digital), Micro-SD (Micro Secure Digital), Mini-SD (Mini Secure Digital), xD (eXtreme Digital), memory stick, or the like. The external memory 434 can be functionally connected to the electronic device 400 through various interfaces. According to an embodiment, the electronic device 400 further includes a storage device or medium such as a hard drive.

The sensor module 440 measures physical quantity or senses an operating status of the electronic device 400, and then convert measured or sensed information into electric signals. The sensor module 440 includes, for example, at least one of a gesture sensor 440A, a gyro sensor 440B, an barometer sensor 440C, a magnetic sensor 440D, an acceleration sensor 440E, a grip sensor 440F, a proximity sensor 440G, a color sensor 440H (for example, RGB (Red, Green, Blue) sensor), a biometric sensor 440I, a temperature-humidity sensor 440J, an illumination sensor 440K, and a UV (ultraviolet) sensor 440M. Additionally or alternatively, the sensor module 440 includes, for example, an E-nose sensor (not shown), an EMG (electromyography) sensor (not shown), an EEG (electroencephalogram) sensor (not shown), an ECG (electrocardiogram) sensor (not shown), an IR (infrared) sensor (not shown), an iris scan sensor (not shown), or a finger scan sensor (not shown). Also, the sensor module 440 includes a control circuit for controlling one or more sensors equipped therein.

The input unit 450 includes a touch panel 452, a digital pen sensor 454, a key 456, or an ultrasonic input unit 458. The touch panel 452 recognizes a touch input in a manner of capacitive type, resistive type, infrared type, or ultrasonic type. Also, the touch panel 452 further includes a control circuit. In case of a capacitive type, a physical contact or proximity can be recognized. The touch panel 452 further includes a tactile layer. In this case, the touch panel 452 offers a tactile feedback to a user.

The digital pen sensor 454 is formed in the same or similar manner as receiving a touch input or by using a separate recognition sheet. The key 456 includes, for example, a physical button, an optical key, or a keypad. The ultrasonic input unit 458 is a specific device capable of identifying data by sensing sound waves with a microphone 288 in the electronic device 400 through an input tool that generates ultrasonic signals, thus allowing wireless recognition. According to an embodiment, the electronic device 400 receives a user input from any external device (for example, a computer or a server) connected thereto through the communication module 420.

The display module 460 (for example, the LCD module 160) includes a panel 462, a hologram 464, or a projector 466. The panel 462 can be, for example, LCD (Liquid Crystal Display), AM-OLED (Active Matrix Organic Light Emitting Diode), or the like. The panel 462 has a flexible, transparent or wearable form. The panel 462 can be formed of a single module with the touch panel 452. The hologram 464 shows a stereoscopic image in the air using interference of light. The projector 466 projects an image onto a screen, which can be located at the inside or outside of the electronic device 400. According to an embodiment, the display module 460 further includes a control circuit for controlling the panel 462, the hologram 464, and the projector 466.

The interface 470 includes, for example, an HDMI (High-Definition Multimedia Interface) 472, a USB (Universal Serial Bus) 474, an optical interface 476, or a D-sub (D-subminiature) 478. The interface 470 is contained, for example, in the communication interface 150 shown in FIG. 1. Additionally or alternatively, the interface 470 includes, for example, an MHL (Mobile High-definition Link) interface, an SD (Secure Digital) card/MMC (Multi-Media Card) interface, or an IrDA (Infrared Data Association) interface.

The audio module 480 performs a conversion between sounds and electric signals. At least part of the audio module 480 is contained, for example, in the input/output interface 140 shown in FIG. 1. The audio module 480 processes sound information inputted or outputted through a speaker 482, a receiver 484, an earphone 486, or a microphone 488.

The camera module 491 is a device capable of obtaining still images and moving images. According to an embodiment, the camera module 491 includes at least one image sensor (for example, a front sensor or a rear sensor), a lens (not shown), an ISP (Image Signal Processor, not shown), or a flash (for example, LED or xenon lamp, not shown).

The power management module 495 manages electric power of the electronic device 400. Although not shown, the power management module 495 includes, for example, a PMIC (Power Management Integrated Circuit), a charger IC, or a battery or fuel gauge.

The PMIC is formed, for example, of an IC chip or SoC. Charging is performed in a wired or wireless manner. The charger IC charges a battery 296 and prevents overvoltage or overcurrent from a charger. According to an embodiment, the charger IC includes a charger IC used for at least one of wired and wireless charging types. A wireless charging type includes, for example, a magnetic resonance type, a magnetic induction type, or an electromagnetic type. Any additional circuit for a wireless charging can be further used such as a coil loop, a resonance circuit, or a rectifier.

The battery gauge measures the residual amount of the battery 496 and a voltage, current or temperature in a charging process. The battery 496 stores or creates electric power therein and supply electric power to the electronic device 400. The battery 496 can be, for example, a rechargeable battery or a solar battery.

The indicator 497 shows thereon a current status (for example, a booting status, a message status, or a recharging status) of the electronic device 400 or of its part (for example, the AP 410). The motor 498 converts an electric signal into a mechanical vibration. Although not shown, the electronic device 400 includes a specific processor (for example, GPU) for supporting a mobile TV. This processor processes media data that comply with standards of DMB (Digital Multimedia Broadcasting), DVB (Digital Video Broadcasting), or media flow.

Each of the above-discussed elements of the electronic device disclosed herein may be formed of one or more components, and its name may be varied according to the type of the electronic device. The electronic device disclosed herein may be formed of at least one of the above-discussed elements without some elements or with additional other elements. Some of the elements may be integrated into a single entity that still performs the same functions as those of such elements before integrated.

The term “module” used in this disclosure may refer to a certain unit that includes one of hardware, software and firmware or any combination thereof. The module may be interchangeably used with unit, logic, logical block, component, or circuit, for example. The module may be the minimum unit, or part thereof, which performs one or more particular functions. The module may be formed mechanically or electronically. For example, the module disclosed herein includes at least one of ASIC (Application-Specific Integrated Circuit) chip, FPGAs (Field-Programmable Gate Arrays), and programmable-logic device, which have been known or are to be developed.

According to various embodiments of the present disclosure, at least part of a device (for example, modules or functions thereof) or a method (for example, operations) according to the present disclosure be implemented, for example, by an instruction stored in a computer-readable storage media in a form of a programming module. When the instruction is executed by at least one processor (for example, the processor 120), the at least one processor may perform a function corresponding to the instruction. The computer readable storage media can be, for example, the memory 130. At least part of the programming module may be implemented (for example, executed) by, for example, the processor 810. At least part of the programming module includes, for example, a module, a program, a routine, sets of instructions and/or a process, or the like to perform one or more functions.

The computer-readable storage media includes Magnetic Media such as hard disk, floppy disk, or magnetic tape, Optical Media such as Compact Disc Read Only Memory (CD-ROM) or Digital Versatile Disc (DVD), Magneto-Optical Media such as floptical disk, and a hardware device such as Read Only Memory (ROM), Random Access Memory (RAM), or flash memory for storing and executing program commands (for example, a programming module). Further, the program command includes a machine language code created by a compiler and a high-level language code executable by a computer using an interpreter. The foregoing hardware device can be configured to be operated according to at least one software module to perforin an operation of the present disclosure, or software modules can be configured to be operated according to the hardware device.

The programming module according to the present disclosure includes at least one of the aforementioned elements, or may omit a part of the aforementioned elements, or further includes additional different elements. The operations performed by the programming module according to the present disclosure or other elements can be executed by a sequential, a parallel, an iterative, or a heuristics method. In addition, some operations may be executed in a different order, or may be omitted, or may add other operations.

Although the present disclosure has been described with an exemplary embodiment, various changes and modifications may be suggested to one skilled in the art. It is intended that the present disclosure encompass such changes and modifications as fall within the scope of the appended claims.

What is claimed is:

1. An LCD module comprising:
a reflective sheet configured to reflect light exiting from a light guide plate and to input the light toward the light guide plate again; and
a metal sheet bonded to a rear surface of the reflective sheet that is opposite to a light incident surface.

2. The LCD module of claim 1, wherein the metal comprises copper (Cu) or aluminum (Al).

3. The LCD module of claim 1, wherein the metal sheet has a thickness of 100 μm or less.

4. The LCD module of claim 1, further comprising:
a flexible printed circuit (FPC),
wherein the metal sheet is attached to or brought into contact with an upper portion of the FPC.

5. The LCD module of claim 4, wherein the metal sheet is attached to the FPC through an adhesive member.

6. The LCD module of claim 4, further comprising:
a bracket,
wherein the FPC is stacked on the bracket.

7. The LCD module of claim 1, further comprising:
a bracket,
wherein the metal sheet is stacked on and attached to the bracket.

8. The LCD module of claim 7, further comprising:
a Flexible Printed Circuit (FPC),
wherein a portion of the FPC is placed on a rear surface of the bracket, which is opposite to the surface of the bracket on which the metal sheet is stacked, through a hole formed in the bracket.

9. The LCD module of claim 1, further comprising:
a bracket,
wherein the metal sheet is stacked on the bracket and is brought into contact with or spaced a predetermined gap apart from the bracket.

10. An electronic device comprising an LCD module, comprising:
a reflective sheet configured to reflect light exiting from a light guide plate and to input the light toward the light guide plate; and
a metal sheet bonded to a rear surface of the reflective sheet that is opposite to a light incident surface.

11. The electronic device of claim 10, wherein the metal comprises copper (Cu) or aluminum (Al).

12. The electronic device of claim 10, wherein the metal sheet has a thickness of 100 μm or less.

13. The electronic device of claim 10, further comprising:
a flexible printed circuit (FPC),
wherein the metal sheet is attached to or brought into contact with an upper portion of the FPC.

14. The electronic device of claim 13, wherein the metal sheet is attached to the FPC through an adhesive member.

15. The electronic device of claim 13, further comprising:
a bracket,
wherein the FPC is stacked on the bracket.

16. The electronic device of claim 10, further comprising:
a bracket,
wherein the metal sheet is stacked on and attached to the bracket.

17. The electronic device of claim 16, further comprising:
a Flexible Printed Circuit (FPC),
wherein a portion of the FPC is placed on a rear surface of the bracket, which is opposite to the surface of the bracket on which the metal sheet is stacked, through a hole formed in the bracket.

18. The electronic device of claim 10, further comprising:
a bracket,
wherein the metal sheet is stacked on the bracket and is brought into contact with or spaced a predetermined gap apart from the bracket.
